(19) United States
(12) Patent Application Publication
(10) Pub. No.: US 2024/0355805 A1
(43) Pub. Date: Oct. 24, 2024

(54) METHOD OF FORMING SEMICONDUCTOR STRUCTURE

(71) Applicant: Taiwan Semiconductor Manufacturing Company, Ltd., Hsinchu (TW)

(72) Inventors: Wei-Ting Yeh, Hsinchu City (TW); Zheng-Yong Liang, Kaohsiung City (TW); Yu-Yun Peng, Hsinchu (TW); Keng-Chu Lin, Ping-Tung (TW)

(73) Assignee: Taiwan Semiconductor Manufacturing Company, Ltd., Hsinchu (TW)

(21) Appl. No.: 18/304,350

(22) Filed: Apr. 21, 2023

(51) Int. Cl. H01L 25/00; H01L 21/683; H01L 23/00; H01L 25/065

(52) U.S. Cl. CPC H01L 25/50; H01L 21/6835; H01L 24/08; H01L 24/83; H01L 25/0657; H01L 2221/68327; H01L 2224/08145; H01L 2224/80896; H01L 2224/83862

(57) ABSTRACT

Provided is a method of forming a semiconductor structure including: bonding a device wafer onto a carrier wafer; forming a support structure between an edge of the device wafer and an edge of the carrier wafer, wherein the support structure surrounds a device layer of the device wafer along a closed path; removing a substrate and a portion of a bonding dielectric layer of the device wafer from a backside of the device wafer to expose the support structures while the support structure is in place; and removing the support structure through an acid etchant.

### BACKGROUND

In recent years, owing to the need in miniaturizing the semiconductor chips, the requirements of wafer thinning process become more severe in semiconductor manufacturing process. Generally, during the wafer thinning process, the grinding process performed on the backside of the semiconductor wafer may cause the wafer edge to be damaged. Subsequently, an edge trimming process may be performed to remove the outer edge of the wafer.

However, the trimmed surface leads to un-recoverable damage on the semiconductor wafer, and the edge step height due to trimming will limits the backside process window. The trimming itself also induce stress on the wafer edge, and potentially impact bonding litho-overlay.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a schematic cross-sectional view of a semiconductor structure in accordance with some embodiments of the present disclosure.

FIG. 2A to FIG. 2I illustrate schematic cross-sectional views of a method of forming a semiconductor structure in accordance with some embodiments of the present disclosure.

FIG. 3 illustrates a schematic top view of a semiconductor structure of FIG. 2A in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

In accordance with some embodiments, a wet-cleanable sealant used in the thinning process of the stacked wafer structure can provide the mechanical support at the edge of the stacked wafer structure during the thinning process and also protect the underlying carrier wafer from damage due to the thinning process. In this case, the edge trimming process can be skipped or omitted. That is, the method is trim-free and the sealant acts as protection layer during thin-down, thus the wafer edge integrity is kept. On the other hand, the trim-free process reduces the edge stress damage, the grinding peeling issue, and the edge bonding litho-overlay impact.

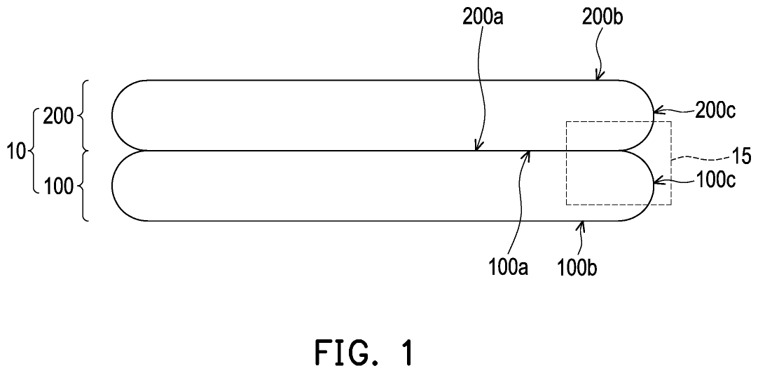

FIG. 1 illustrates a schematic cross-sectional view of a semiconductor structure in accordance with some embodiments of the present disclosure.

Referring to FIG. 1, a first wafer 100 is provided. In some embodiments, the first wafer 100 has a first surface 100a, a second surface 100b opposite to the first surface 100a, and an edge 100c connecting between the first surface 100a and the second surface 100b. For example, a side where the first surface 100a is located may be referred to the front side of the first wafer 100, and the opposite side where the second surface 100b is located may be referred to the backside of the first wafer 100. The first wafer 100 may be of any appropriate size and shape. In some embodiments, the first wafer 100 is a substantially circular wafer. The edge 100c in FIG. 1 is illustrated as curve shaped or a rounded edge. In other embodiments, the first wafer 100 may have a chamfered edge or a beveled edge.

In some embodiments, the first wafer 100 may be a semiconductor wafer such as a silicon bulk wafer or a gallium arsenide wafer. In some embodiments, the first wafer 100 may include, for example, silicon, strained silicon, silicon alloy, silicon carbide, silicon-germanium, silicon-germanium carbide, germanium, a germanium alloy, germanium-arsenic, indium-arsenic, group III-V semiconductors. In some embodiments, the first wafer 100 includes glass or ceramic materials. In the present embodiment, the first wafer 100 is a carrier wafer. That is, the carrier wafer may be a bare silicon wafer which is substantially free of active, devices, passive devices, or any functional devices. However, the embodiments of the present invention are not limited thereto. In some alternative embodiments, the first wafer 100 is a device wafer. The device wafer may include active and passive devices. A wide variety of devices such as transistors, capacitors, resistors, combinations of these, and the like may be used to generate the structural and functional requirements of the design for the device stack. The device wafer may also include an interconnect structure which includes metallization layers and vias formed over the active and passive devices and are designed to connect the various devices to form functional circuitry.

As shown in FIG. 1, a second wafer 200 is provided. In some embodiments, the second wafer 200 has a first surface 200a, a second surface 200b opposite to the first surface 200a, and an edge 200c connecting between the first surface 200a and the second surface 200b. For example, a side where the first surface 200a is located may be referred to the front side of the second wafer 200, and the opposite side where the second surface 200b is located may be referred to the backside of the second wafer 200. In the present embodiment, the front side 200a of the second wafer 200 is referred to as an active surface, while the backside of the second wafer 200 is referred to as a non-active surface. The second wafer 200 may be of any appropriate size and shape. In some embodiments, the second wafer 200 is a substantially circular wafer. The edge 200c in FIG. 1 is illustrated as curve shaped or a rounded edge. In other embodiments, the second wafer 200 may have a chamfered edge or a beveled edge.

In some embodiments, the second wafer 200 may be a semiconductor wafer such as a silicon bulk wafer or a gallium arsenide wafer. In some embodiments, the second wafer 200 may include, for example, silicon, strained silicon, silicon alloy, silicon carbide, silicon-germanium, silicon-germanium carbide, germanium, a germanium alloy, germanium-arsenic, indium-arsenic, group III-V semiconductors. In some embodiments, the second wafer 200 includes glass or ceramic materials. In the present embodiment, the second wafer 200 is different from the first wafer 100. For example, the first wafer 100 is a carrier wafer, while the second wafer 200 is a device wafer. The device wafer may include active and passive devices. A wide variety of devices such as transistors, capacitors, resistors, combinations of these, and the like may be used to generate the structural and functional requirements of the design for the device stack. The device wafer may also include an interconnect structure which includes metallization layers and vias formed over the active and passive devices and are designed to connect the various devices to form functional circuitry.

The first wafer 100 and the second wafer 200 may be bonded to each other to form a stacked wafer structure 10. In some embodiments, the first wafer 100 is bonded to the second wafer 200 through a directly bonding method. Specifically, the second wafer 200 is turned upside down, so that the first surface 200a of the second wafer faces toward the first surface 100a of the first wafer 100, the first surface 200a of the second wafer is in direct contact with the first surface 100a of the first wafer 100, and then bonded together by the application of pressure and heat. In some embodiments, the first wafer 100 and the second wafer 200 have the same diameter. In other embodiments, the first wafer 100 and the second wafer 200 may have different diameters. The dimension of the first wafer 100 and the second wafer 200 may depend on the design requirement and construe no limitation in the disclosure. When bonding the first wafer 100 and the second wafer 200, the molecular bonding technique may be employed. For example, bringing the first surface 100a of the first wafer 100 and the top surface 200a of the second wafer 200 into direct contact, and the first wafer 100 and the second wafer 200 are bonded through Van der Waals force without using a specific bonding material or an adhesive. The bonding process will be discussed in the following paragraphs.

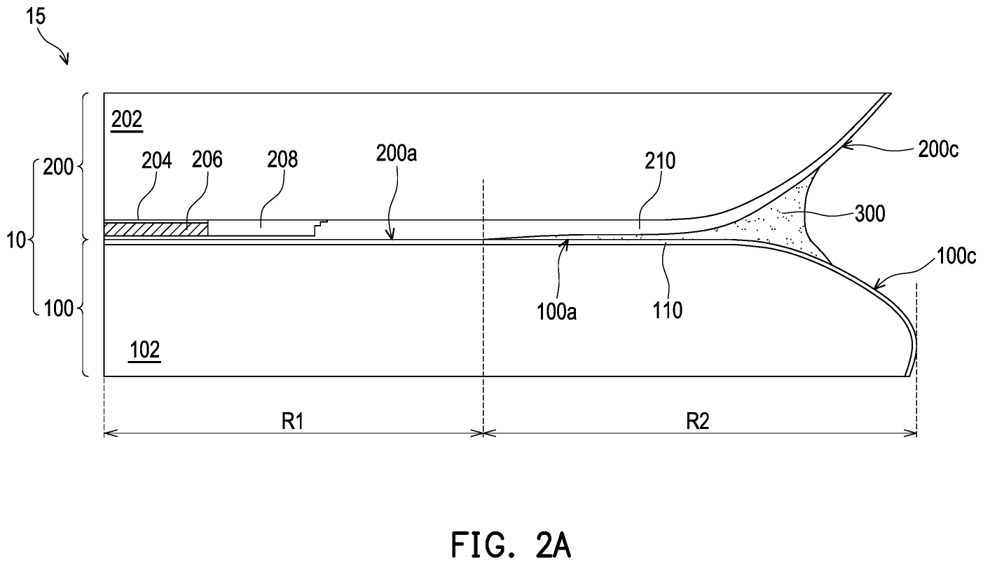

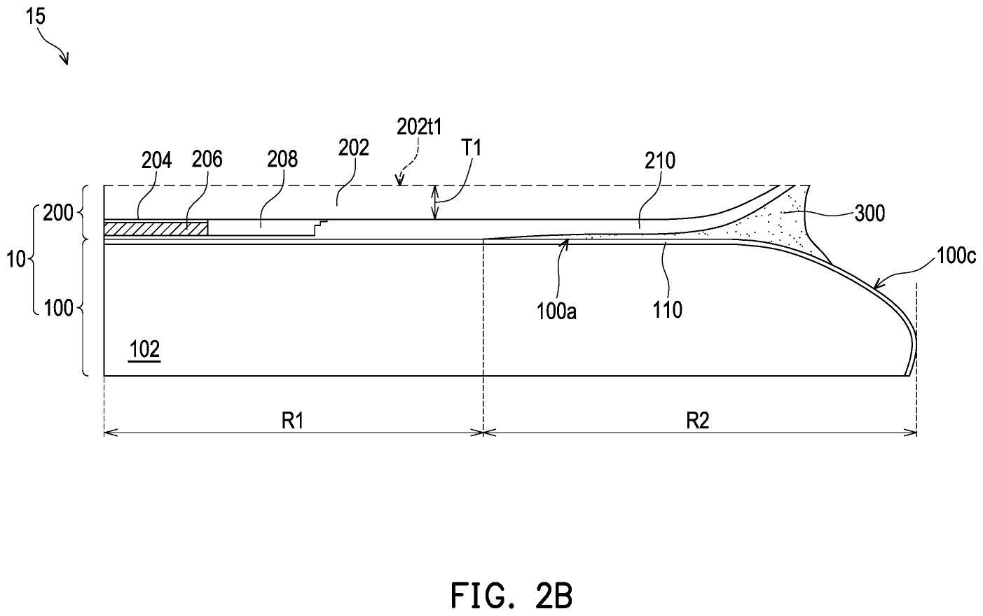

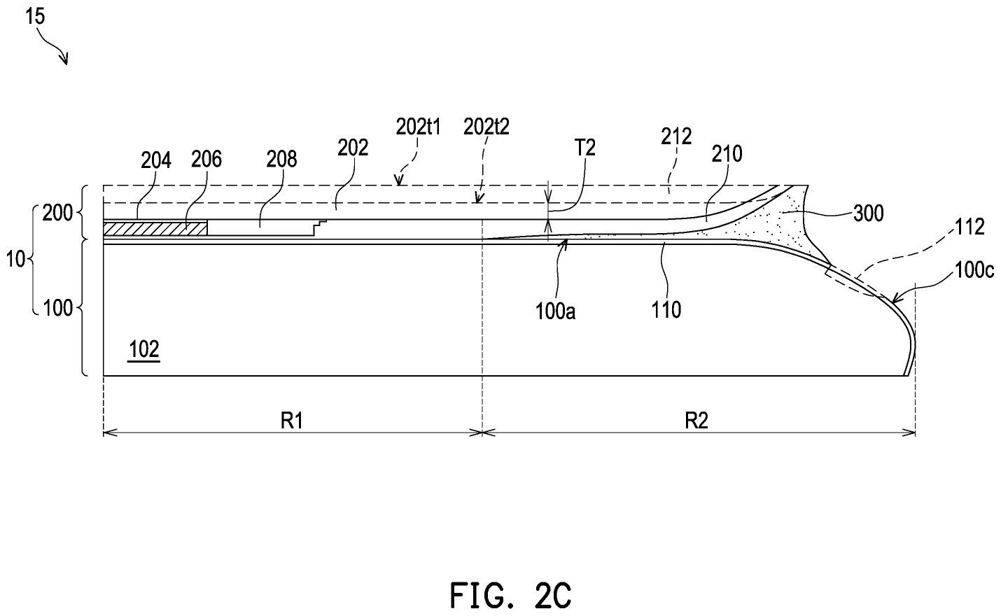

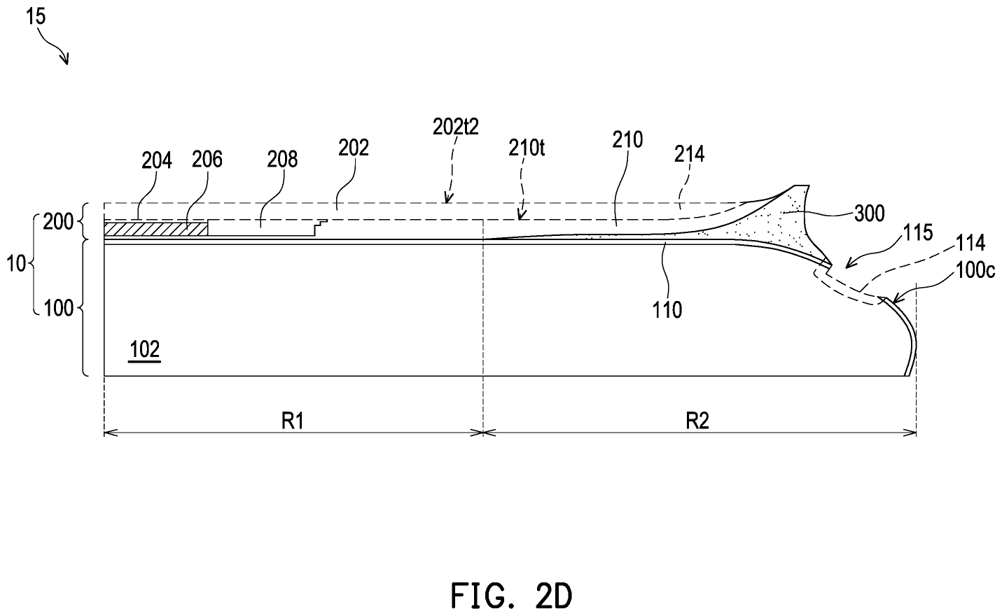

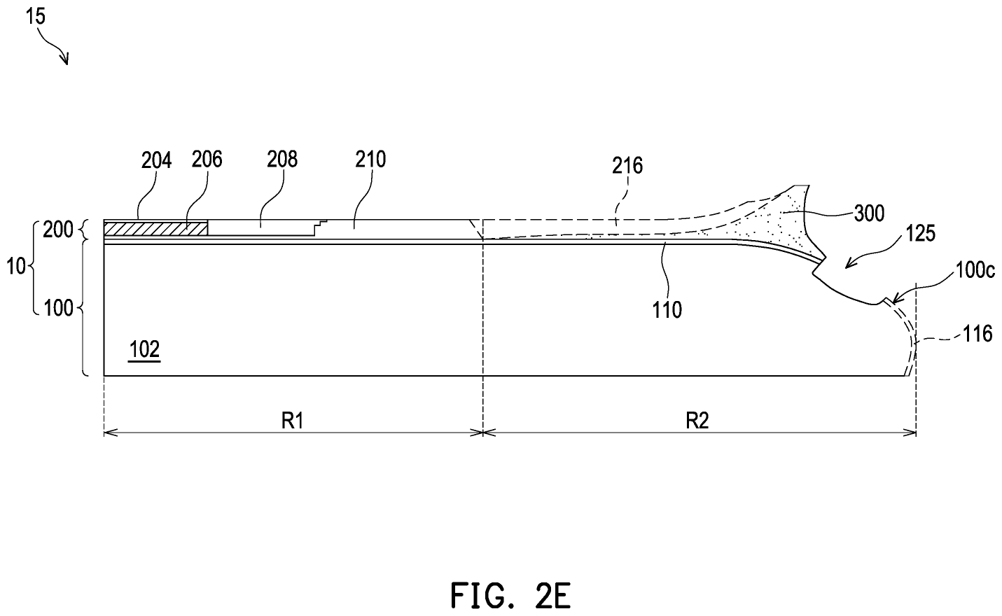

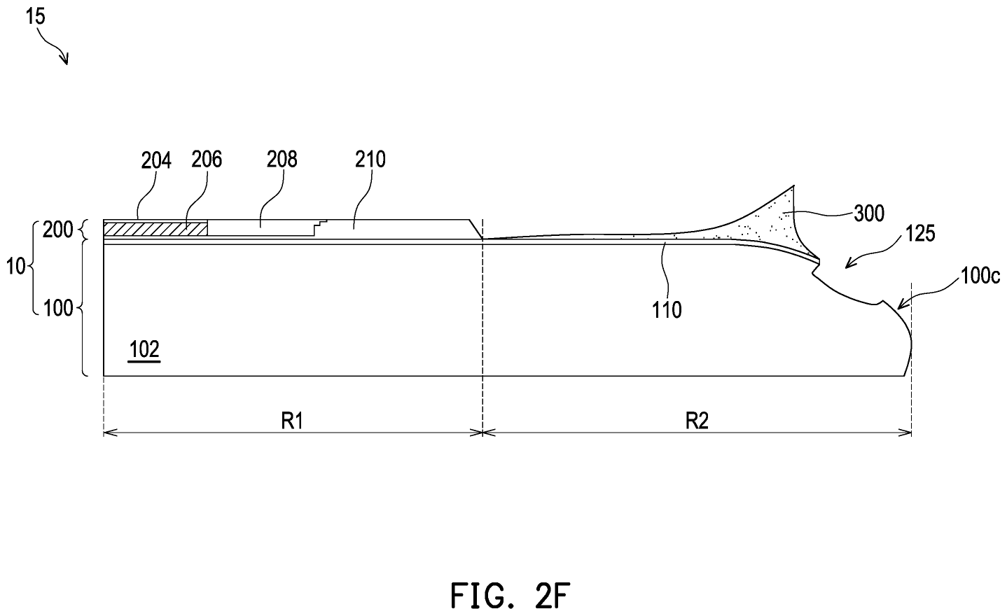

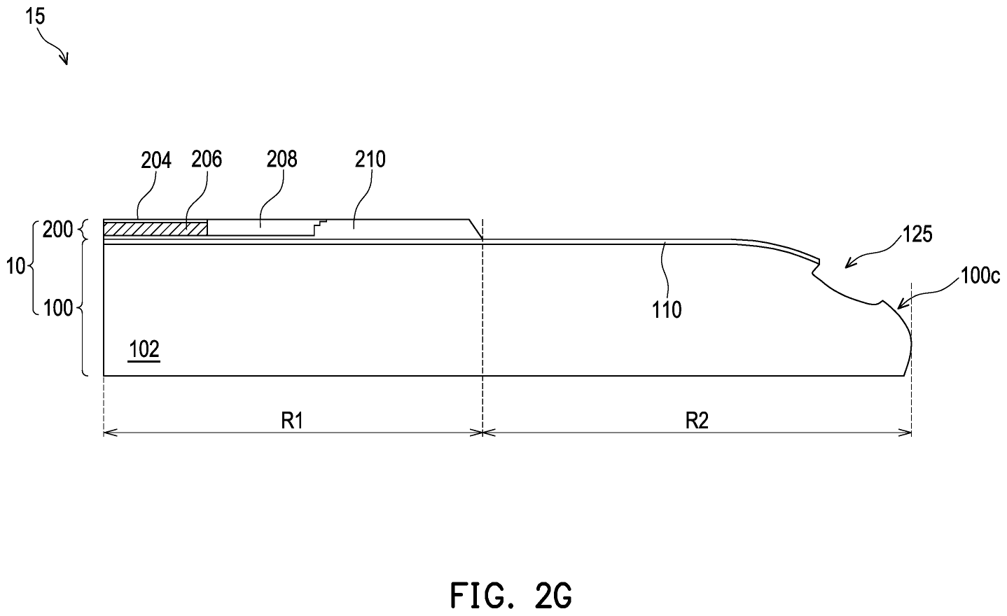

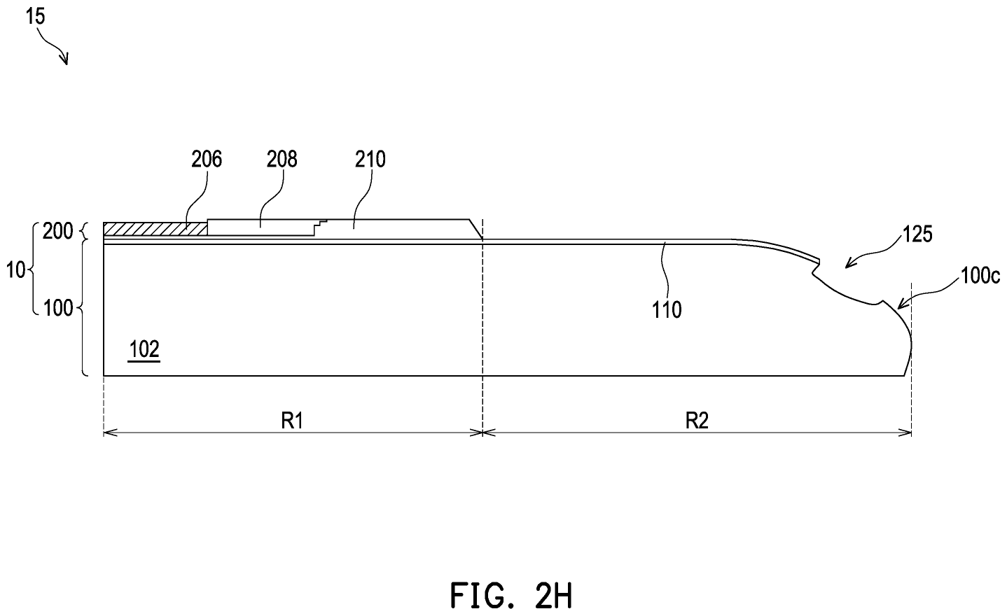

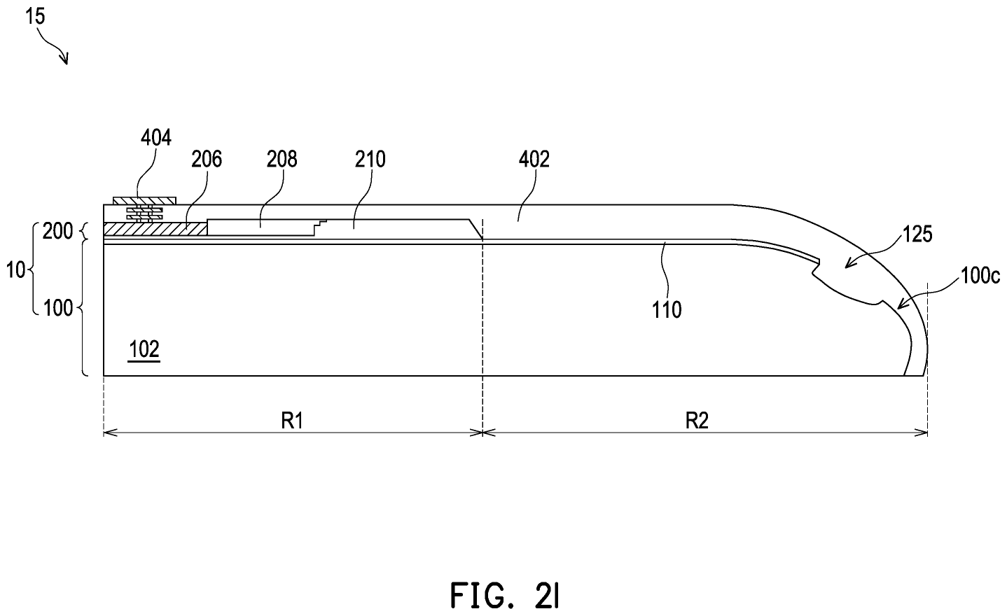

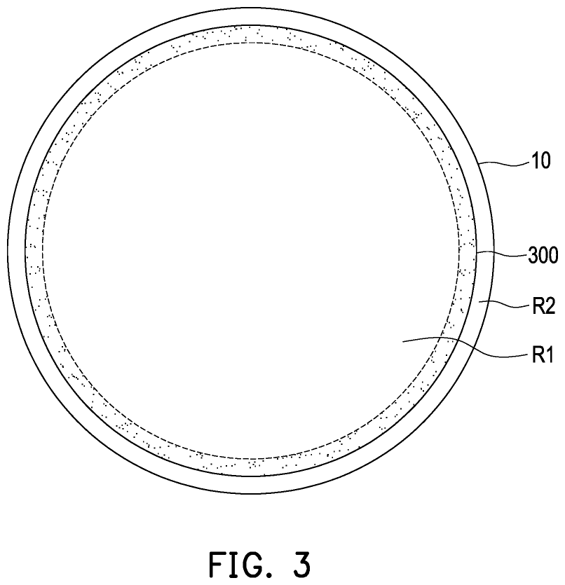

FIG. 2A to FIG. 2I illustrate schematic cross-sectional views of a method of forming a semiconductor structure in accordance with some embodiments of the present disclosure. FIG. 3 illustrates a schematic top view of a semiconductor structure of FIG. 2A in accordance with some embodiments of the present disclosure. It should be noted that the following drawings only illustrate an enlarged view of a region 15 of FIG. 1, other components other than the region 15 are omitted.

Referring to FIG. 2A, the first wafer 100 includes a first substrate 102 and a first bonding dielectric layer 110. In some embodiments, the first substrate 102 may be made of silicon or other semiconductor materials. For example, the first substrate 102 may be a silicon substrate. Alternatively, or additionally, the first substrate 102 may include other elementary semiconductor materials such as germanium. In some embodiments, the first substrate 102 is made of a compound semiconductor such as silicon carbide, gallium arsenic, indium arsenide or indium phosphide. In some embodiments, the first substrate 102 is made of an alloy semiconductor such as silicon germanium, silicon germanium carbide, gallium arsenic phosphide, or gallium indium phosphide. Furthermore, the first substrate 102 may be a semiconductor on insulator such as silicon on insulator (SOI) or silicon on sapphire.

The first bonding dielectric layer 110 is formed to cover the surface of the first substrate 102. In some embodiments, the first bonding dielectric layer 110 includes silicon oxide, silicon nitride, silicon oxynitride, or a combination thereof. The first bonding dielectric layer 110 may be formed by depositing a dielectric material through a suitable process such as a thermal oxidation, a chemical vapor deposition (CVD) or the like, and then performing a planarization process on the dielectric material. In some embodiments, the planarization process includes a chemical mechanical polish (CMP) process, an etching back process, or a combination thereof.

In some embodiments, the second wafer 200 at least includes a second substrate 202, a stop layer 204, a device layer 206, a buffer layer 208, and a second bonding dielectric layer 210. In some embodiments, the second substrate 202 may be made of silicon or other semiconductor materials. For example, the second substrate 202 may be a silicon substrate. Alternatively, or additionally, the second substrate 202 may include other elementary semiconductor materials such as germanium. In some embodiments, the second substrate 202 is made of a compound semiconductor such as silicon carbide, gallium arsenic, indium arsenide or indium phosphide. In some embodiments, the second substrate 202 is made of an alloy semiconductor such as silicon germanium, silicon germanium carbide, gallium arsenic phosphide, or gallium indium phosphide. Furthermore, the second substrate 202 may be a semiconductor on insulator such as silicon on insulator (SOI) or silicon on sapphire.

The stop layer 204 may be formed on the second substrate 202. In some embodiments, the stop layer 204 may be made of a semiconductor material such as SiGe or the like, and may be formed by any suitable process such as an epitaxial growth process, an atomic layer deposition (ALD) process, a CVD process or the like.

The device layer 206 may be formed on the stop layer 204. In some embodiments, the device layer 206 is formed over the stop layer 204 in a front-end-of-line (FEOL) process. The device layer 206 includes a wide variety of devices. In some embodiments, the devices comprise active components, passive components, or a combination thereof. In some embodiments, the devices may include integrated circuits devices. The devices are, for example, transistors, capacitors, resistors, diodes, photodiodes, fuse devices, or other similar devices. In some embodiments, the device layer 206 includes a gate structure, source and drain regions, and isolation structures, such as shallow opening isolation (STI) structures (not shown). In the device layer 206, various N-type metal-oxide semiconductor (NMOS) and/or P-type metal-oxide semiconductor (PMOS) devices, such as transistors or memories and the like, may be formed and interconnected to perform one or more functions. Other devices, such as capacitors, resistors, diodes, photodiodes, fuses and the like may also be formed over the stop layer 204. The functions of the devices may include memory, processors, sensors, amplifiers, power distribution, input and/or output circuitry, or the like.

In addition, the interconnect structure (not shown) is formed over the device layer 206. In detail, the interconnect structure includes an insulating material and a plurality of metal features. The metal features are formed in the insulating material and electrically connected to the device layer 206. In some embodiments, the insulating material includes an inner-layer dielectric (ILD) layer on the device layer 206, and at least one inter-metal dielectric (IMD) layer over the ILD layer. In some embodiments, the insulating material includes silicon oxide, silicon nitride, silicon oxynitride, tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), low-k dielectric material, other suitable dielectric material, or combinations thereof. Exemplary low-k dielectric materials include FSG, carbon doped silicon oxide, Black Diamond® (Applied Materials of Santa Clara, California), Xerogel, Aerogel, amorphous fluorinated carbon, Parylene, BCB, SiLK (Dow Chemical, Midland, Michigan), polyimide, other low-k dielectric material, or combinations thereof. In some alternatively embodiments, the insulating material may be a single layer or multiple layers. In some embodiments, the metal features include plugs and metal lines. The plugs may include contacts formed in the ILD layer, and vias formed in the IMD layer. The contacts are formed between and in connect with the device layer 206 and a bottom metal line. The vias are formed between and in connect with two metal lines. The metal features may be made of tungsten (W), copper (Cu), copper alloys, aluminum (Al), aluminum alloys, or a combination thereof. In some alternatively embodiments, a barrier layer (not shown) may be formed between the metal features and the insulating material to prevent the material of the metal features from migrating to or diffusion to the device layer 206. A material of the barrier layer includes tantalum, tantalum nitride, titanium, titanium nitride, cobalt-tungsten (CoW) or a combination thereof, for example.

The buffer layer 208 may be formed aside the device layer 206. In some embodiments, the buffer layer 208 includes at least one low-k dielectric material layer including a dielectric material having a dielectric constant less than 3.9, and may be formed by any suitable process such as a CVD process, an ALD process or the like, and then performing a planarization process on the dielectric material. In one embodiment, the dielectric material of the at least one low-k dielectric material layer comprises a porous dielectric material having a dielectric constant in a range from 2.0 to 2.8, which is known in the art as an extremely low-k (ELK) dielectric material. In the present embodiment, the buffer layer 208 is free of any metal feature therein, only includes the low-k dielectric material.

The second bonding dielectric layer 210 is formed to cover the surfaces of the second substrate 202, the device layer 206, and the buffer layer 208. In some embodiments, the second bonding dielectric layer 210 includes silicon oxide, silicon nitride, silicon oxynitride, or a combination thereof. The second bonding dielectric layer 210 may be formed by depositing a dielectric material through a suitable process such as a thermal oxidation, a CVD or the like, and then performing a planarization process on the dielectric material. In some embodiments, the planarization process includes a CMP process, an etching back process, or a combination thereof.

The second wafer 200 is turned upside down, so that the first surface 200a of the second wafer faces toward the first surface 100a of the first wafer 100. In some embodiments, before the second wafer 200 is bonded to the first wafer 100, the first bonding dielectric layer 110 may be aligned with the second bonding dielectric layer 210 by using an optical sensing method. After the alignment is achieved, the first bonding dielectric layer 110 is in direct contact with the second bonding dielectric layer 210 and then bonded together by the application of pressure and heat. In this case, the bonding of the first bonding dielectric layer 110 bonded to the second bonding dielectric layer 210 may be referred to as a dielectric-to-dielectric bonding or directly bonding. After the second wafer 200 is bonded to the first wafer 100, an annealing process may be performed to strengthen the bonding between the first wafer 100 and the second wafer 200. The temperature of the annealing process may depend on the design requirement. For example, the higher the temperature of the annealing process, the greater the resulting bonding strength. In other embodiments in which the electrical components are distributed in the device layer 206 of the second wafer 200, the temperature of the annealing process is limited to relatively low so as not to damage the electrical components.

As shown in FIG. 2A, after bonding the first wafer 100 and the second wafer 200, the stacked wafer structure 10 is accomplished. In detail, the stacked wafer structure 10 may include a first region R1 and a second region R2. The second region R2 may be a ring region to surround the first region R1, as shown in the top view of FIG. 3. In some embodiments, the first region R1 is referred to as a bonding region, which means the first bonding dielectric layer 110 is in direct contact with the second bonding dielectric layer 210 in the bonding region R1. In some alternative embodiments, the first region R1 is referred to a device region, which means the device layer 206 is located therein. On the other hand, the second region R2 is referred to as a non-bonding region, which means the first bonding dielectric layer 110 is not in direct contact with the second bonding dielectric layer 210 in the non-bonding region R2. In some alternative embodiments, the second region R2 is referred to a peripheral region, which means no device layer is located therein.

After bonding the first wafer 100 and the second wafer 200, a support structure 300 is formed between the edge 100c of the first wafer 100 and the edge 200c of the second wafer 200. Specifically, the support structure 300 may be formed by injecting a sealant material into a gap between the edge 100c of the first wafer 100 and the edge 200c of the second wafer 200, so that the sealant material extends between the first bonding dielectric layer 110 and the second bonding dielectric layer 110 in the non-bonding region R2. Next, a curing process is performed to cure the sealant material as the support structure 300. In some embodiments, the sealant material is originally in a liquid state, and the curing process is used to convert the sealant material from the liquid state to the solid state. In some embodiments, the sealant material includes a modified epoxy-based polymer or an acrylic-based polymer, which enables the polymer cross-link with minimal volume change under the thermal treatment. In some embodiments, the temperature of the curing process is less than 400° C., which means less than the process temperature of the back-end-of-line (BEOL). As shown in FIG. 2A, the edge of the cured support structure 300 may be laterally recessed from the edge 100c of the first wafer 100 and the edge 200c of the second wafer 200. That is, the support structure 300 at least covers the first surface 100a of the first wafer 100 in the flat region of the non-bonding region R2, while exposes the first surface 100a of the first wafer 100 in the bevel region of the non-bonding region R2. After performing the curing process, the support structure 300 may cover the first surface 100a of the first wafer 100 in the non-bonding region R2 to protect the first wafer 100 from damage in subsequent thinning and/or etching processes. In this case, the support structure 300 may be referred to as a protective structure. In the top view of FIG. 3, the support structure 300 may be located in the peripheral region R2 and laterally surround the device layer 206 (FIG. 2A) in the device region R1 along a closed path. In the present embodiment, the sealant material includes some special chemical group embedded in the body of polymer chain, which enables the polymer network dissociation under an acidic environment, such as in an acid etchant with sulfuric peroxide mixture (SPM, a mixture of sulfuric acid (H₂SO₄) and hydrogen peroxide (H₂O₂)) or hydrogen fluoride (HF). The detail removal process will be discussed in the following paragraphs.

Referring to FIG. 2B through FIG. 2E, a thinning process is performed on the backside 200b (FIG. 1) of the second wafer 200 to expose the stop layer 204 of the second wafer 200 while the support structure 300 is in place. In some embodiments, the thinning process includes a first thinning process, a second thinning process, and a third thinning process. Specifically, the first thinning process may be performed on the second wafer 200 to remove a first portion of the second substrate 202 of the second wafer 200 from the backside 200b (FIG. 1) of the second wafer 200 to a first thickness T1. In some embodiments, the first thickness T1 is in a range from about 13 μm to about 80 μm, such as 13 μm, although lesser and greater thicknesses may also be used depending on the grinding sub-surface damage and the total thickness variation control in the subsequent wet etching processes. The second wafer 200 is thinned (i.e., the thickness of the second substrate 202 is reduced) by performing a mechanical machining process, and the mechanical machining process includes, for example, a grinding process, a chemical mechanical polishing (CMP) process, or other suitable polishing process. In some embodiments, the second wafer 200 is thinned from the backside 200b downward towards the front side 200a. For example, during performing the thinning process, the stacked wafer structure 10 is held by a wafer holder (not illustrated). In some embodiments, the second wafer 200 may be thinned until the remained thickness of the second wafer 200 almost equal to or slightly less than the first thickness T1. Since the edge 200c of the second wafer 200 is supported by the support structure 300 during performing the first thinning process, so that the chipping and delamination issues due to the sharp edge of the thinned wafer can be effectively eliminated. In addition, a portion of the second bonding dielectric layer 210 and a portion of the support structure 300 on the edge 200c of the second wafer 200 are also removed in the first thinning process.

Next, a second thinning process may be performed on the second wafer 200 to remove a second portion 212 of the second wafer 200 to a second thickness T2. In some embodiments, the second thickness T2 is in a range from about 1 μm to about 2 μm, such as 1 μm. That is, the top surface 202t1 of the second substrate 202 is thinned to the top surface 202t2 after performing the second thinning process, as shown in FIG. 2C. In some embodiments, the second thinning process includes a wet etching process using an etchant with HNO₃ and HF, which HNO₃ targets for Si oxidation and HF targets for SiO etching. The second thinning process may have low Si-to-SiO selectivity, high throughput, and perfect total thickness control. In addition, a portion 112 of the first wafer 100 on the edge 100c is also removed in the second thinning process. In some embodiments, the portion 112 includes a portion of first bonding dielectric layer 110 and a portion of the first substrate 102.

Then, a third thinning process may be performed on the second wafer 200 to remove a third portion 214 of the second wafer 200 to expose the stop layer 204 and the second bonding dielectric layer 210. That is, the top surface 202t2 of the second substrate 202 is thinned to expose the top surface 210t of the second bonding dielectric layer 210 after performing the third thinning process, as shown in FIG. 2D. In the embodiment, the second substrate 202 is completely removed after performing the third thinning process. In some embodiments, the third thinning process includes a wet etching process using an etchant with TMAH or NH₄OH, which offers OH-group for Si etching. In some embodiments, a removal rate of the second thinning process is greater than a removal rate of the third thinning process. As such, the third thinning process may provide a high etching selectivity of the silicon substrates 102 and 202 relative to the stop layer 206 for backside landing control, while the second thinning process may be used for the high throughput of Si removal. That is, the etching rate of the silicon substrates 102 and 202 is greater than the etching rate of the stop layer 206 during the third thinning process. In addition, a portion 114 of the first wafer 100 is also removed from the recess 115 on the edge 100c in the third thinning process.

Referring to FIG. 2D and FIG. 2E, a first etching process may be performed to remove the second bonding dielectric layer 210 overlying the support structure 300. In some embodiments, the first etching process includes a wet etching process using an etchant with HF. Specifically, the HF etchant is positioned sprayed onto the second bonding dielectric layer 210 overlying the support structure 300 by the nozzle to remove the second bonding dielectric layer 210 and expose the support structure 300. In some alternative embodiments, the first etching process includes a dry etching process using a fluorine-containing etching gas. In detail, a mask ring is used to cover the device region R1 while expose the peripheral region R2, and then the fluorine-containing etching gas is applied to remove the second bonding dielectric layer 210 overlying the support structure 300. The first etching process may provide a high etching selectivity of the second bonding dielectric layer 210 relative to the first substrate 102. That is, the etching rate of the second bonding dielectric layer 210 is greater than the etching rate of the first substrate 102 during the first etching process. In addition, a portion of the support structure 300 and a portion of the first bonding dielectric layer 110 on the edge 100c are also removed in the first etching process.

After performing the first etching process, as shown in FIG. 2F, the support structure 300 is exposed and one or more recesses 125 are formed on the bevel region of the edge 100c of the first wafer 100. Compared with the wafer having a staircase surface resulted in the conventional trimming process, the edge 100c of the first wafer 100 may have an uneven surface and/or an irregular surface.

Referring to FIG. 2F and FIG. 2G, a second etching process is performed to remove the support structure 300 and expose the first bonding dielectric layer 110 of the first wafer 100 on the peripheral region R2. That is, after performing the second etching process, the first bonding dielectric layer 110 still covers the peripheral region R2 of the first wafer 100, so that the top surface of the first substrate 102 of the first wafer 100 on the peripheral region R2 is flat. In this case, the top surface of the first substrate 102 of the first wafer 100 in the device region R1 is substantially level with the top surface of the first substrate 102 of the first wafer 100 in the peripheral region R2. In some embodiments, the second etching process includes a wet etching process using an (acid) etchant with sulfuric peroxide mixture (SPM, a mixture of H₂SO₄ and H₂O₂) or HF. Specifically, the material of the support structure 300 is designed to react with the wet chemicals and be wet cleanable. In such embodiment, the support structure 300 includes a modified epoxy-based polymer or an acrylic-based polymer, which is configured to dissociate in the acidic environment such as SPM or HF. In some alternative embodiments, the support structure 300 is also configured to dissociate in the alkaline environment. It should be noted that, in the present embodiment, the thin-down process is trim-free to reduce the edge stress damage, the grinding peeling issue, and the edge bonding litho-overlay impact. In addition, compared with the grinding process to remove the sealant, the thin-down process by the wet etching process offers a damage-less way to avoid the edge-crack issue. Further, compared with the conventional Si dry etching process (typically long process time), the thin-down process by the wet etching process offers a cost reduction way.

Referring to FIG. 2H and FIG. 2I, after removing the support structure 300, the stop layer 204 may be removed. In some embodiments, the stop layer 204 is removed to expose the device layer 206, as shown in FIG. 2H. The stop layer 204 may be removed by any suitable process such as wet etching process or dry etching process which is not limited thereto. In some embodiments, the etching process for removing the stop layer 204 may offer the high etching selectivity of the stop layer 204 relative to the bonding dielectric layers 110, 210, and the silicon structure 102.

After removing the stop layer 204, a backside metallization structure 404 is formed on the device layer 206, as shown in FIG. 2I. Specifically, a dielectric layer 402 is formed to cover the structure illustrated in FIG. 2H. In some embodiments, the dielectric layer 402 includes silicon oxide, silicon nitride, silicon oxynitride, tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), low-k dielectric material, other suitable dielectric material, or combinations thereof. Exemplary low-k dielectric materials include FSG, carbon doped silicon oxide, Black Diamond® (Applied Materials of Santa Clara, California), Xerogel, Aerogel, amorphous fluorinated carbon, Parylene, BCB, SiLK (Dow Chemical, Midland, Michigan), polyimide, other low-k dielectric material, or combinations thereof. In some alternatively embodiments, the dielectric layer 402 may be a single layer or multiple layers.

Then, the backside metallization structure 404 is formed in/on the dielectric layer 402. The backside metallization structure 404 may include metallization layers and the conductive vias. The metallization layers may be formed over the device layer 206 and are designed to connect the various devices to form functional circuitry. The metallization layers may be formed of conductive material (e.g., copper) with vias interconnecting the layers of conductive material and may be formed through any suitable process (such as deposition, damascene, dual damascene, or the like). In some embodiments, the backside metallization structure 404 is used to electrically connect the device layer 206 and the external components formed on the backside, thereby providing more flexible routing and effectively scaling down the chip size. As such, the thin-down method of the present application can be applied to more advanced node technology.

According to some embodiments, a method of forming a semiconductor structure includes: providing a first wafer with a first bonding dielectric layer; providing a second wafer with a device layer sandwiched between a stop layer and a second bonding dielectric layer; bonding the first wafer to the second wafer to form a stacked wafer structure; forming a support structure between an edge of the first wafer and an edge of the second wafer; performing a thinning process on a backside of the second wafer to expose the stop layer of the second wafer while the support structure is in place; performing a first etching process to remove the second bonding dielectric layer overlying the support structure; and performing a second etching process to remove the support structure and expose the first bonding dielectric layer of the first wafer.

According to some embodiments, a method of forming a semiconductor structure includes: bonding a first wafer to a second wafer by contacting a first bonding dielectric layer of the first wafer to a second bonding dielectric layer of the second wafer; forming a protective structure between an edge of the first wafer and an edge of the second wafer to cover a peripheral region of the first wafer; when the protective structure covers the peripheral region of the first wafer, removing a substrate of the second wafer from a backside of the second wafer until the second bonding dielectric layer overlying the protective structure is exposed; performing a first etching process to remove the second bonding dielectric layer overlying the protective structure and expose the protective structure; and performing a second etching process to remove the protective structure to expose the peripheral region of the first wafer.

According to some embodiments, a method of forming a semiconductor structure includes: bonding a device wafer onto a carrier wafer; forming a support structure between an edge of the device wafer and an edge of the carrier wafer, wherein the support structure surrounds a device layer of the device wafer along a closed path; removing a substrate and a portion of a bonding dielectric layer of the device wafer from a backside of the device wafer to expose the support structures while the support structure is in place; and removing the support structure through an acid etchant.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor structure, comprising:
providing a first wafer with a first bonding dielectric layer;
providing a second wafer with a device layer sandwiched between a stop layer and a second bonding dielectric layer;
bonding the first wafer to the second wafer to form a stacked wafer structure;
forming a support structure between an edge of the first wafer and an edge of the second wafer;
performing a thinning process on a backside of the second wafer to expose the stop layer of the second wafer while the support structure is in place;
performing a first etching process to remove the second bonding dielectric layer overlying the support structure; and
performing a second etching process to remove the support structure and expose the first bonding dielectric layer of the first wafer.

2. The method of claim 1, wherein the stacked wafer structure comprises a bonding region and a non-bonding region surrounding the bonding region, the first bonding dielectric layer is in direct contact with the second bonding dielectric layer in the bonding region, while the first bonding dielectric layer is not in contact with the second bonding dielectric layer in the non-bonding region.

3. The method of claim 2, wherein the forming the support structure comprises:
injecting a sealant material into a gap between the edge of the first wafer and the edge of the second wafer, so that the sealant material extends between the first bonding dielectric layer and the second bonding dielectric layer in the non-bonding region; and
performing a curing process to cure the sealant material as the support structure.

4. The method of claim 3, wherein the sealant material comprises a modified epoxy-based polymer or an acrylic-based polymer.

5. The method of claim 1, wherein the thinning process comprises:
a first thinning process including a grinding process;
a second thinning process including a wet etching process using an etchant with HNO₃ and HF; and
a third thinning process including a wet etching process using an etchant with TMAH or NH₄OH.

6. The method of claim 5, wherein a removal rate of the second thinning process is greater than a removal rate of the third thinning process.

7. The method of claim 1, wherein the first etching process comprises a wet etching process using an etchant with HF.

8. The method of claim 1, wherein the second etching process comprises a wet etching process using an etchant with a mixture of sulfuric acid and hydrogen peroxide or HF.

9. The method of claim 1, wherein after removing the support structure, the method further comprises:
removing the stop layer to expose the device layer; and
forming a backside metallization structure on the device layer.

10. A method of forming a semiconductor structure, comprising:
bonding a first wafer to a second wafer by contacting a first bonding dielectric layer of the first wafer to a second bonding dielectric layer of the second wafer;
forming a protective structure between an edge of the first wafer and an edge of the second wafer to cover a peripheral region of the first wafer;
when the protective structure covers the peripheral region of the first wafer, removing a substrate of the second wafer from a backside of the second wafer until the second bonding dielectric layer overlying the protective structure is exposed;
performing a first etching process to remove the second bonding dielectric layer overlying the protective structure and expose the protective structure; and
performing a second etching process to remove the protective structure to expose the peripheral region of the first wafer.

11. The method of claim 10, wherein after performing the second etching process, the first bonding dielectric layer still covers the peripheral region of the first wafer, so that a top surface of a substrate of the first wafer on the peripheral region is flat.

12. The method of claim 10, wherein the first wafer comprises a device region and the peripheral area surrounding the device region, after performing the second etching process, a top surface of a substrate of the first wafer in the device region is substantially level with a top surface of a substrate of the first wafer in the peripheral region.

13. The method of claim 10, wherein the forming the protective structure comprises:
injecting a sealant material into a gap between the edge of the first wafer and the edge of the second wafer, so that the sealant material extends between the first bonding dielectric layer and the second bonding dielectric layer; and
performing a curing process to cure the sealant material as the protective structure.

14. The method of claim 13, wherein the sealant material comprises a modified epoxy-based polymer or an acrylic-based polymer.

15. The method of claim 10, wherein the protective structure is configured to dissociate in an acidic environment.

16. The method of claim 10, wherein the first etching process comprises a wet etching process using an etchant with HF.

17. The method of claim 10, wherein the second etching process comprises a wet etching process using an etchant with a mixture of sulfuric acid and hydrogen peroxide or HF.

18. A method of forming a semiconductor structure, comprising:
bonding a device wafer onto a carrier wafer;
forming a support structure between an edge of the device wafer and an edge of the carrier wafer, wherein the support structure surrounds a device layer of the device wafer along a closed path;
removing a substrate and a portion of a bonding dielectric layer of the device wafer from a backside of the device wafer to expose the support structures while the support structure is in place; and
removing the support structure through an acid etchant.

19. The method of claim 18, further comprising removing a portion of the carrier wafer in a bevel region during removing the substrate and the portion of the bonding dielectric layer of the device wafer from the backside of the device wafer, so that a surface of the carrier wafer in the bevel region has one or more recesses.

20. The method of claim 18, wherein the acid etchant comprises a mixture of sulfuric acid and hydrogen peroxide or HF.
